(19) United States
(12) Patent Application Publication
(10) Pub. No.: US 2025/0054729 A1
(43) Pub. Date: Feb. 13, 2025

(54) SUBSTRATE PROCESSING TOOL WITH HIGH-SPEED MATCH NETWORK IMPEDANCE SWITCHING FOR RAPID ALTERNATING PROCESSES

(71) Applicant: LAM RESEARCH CORPORATION, Fremont, CA (US)

(72) Inventor: Shen PENG, Dublin, CA (US)

(21) Appl. No.: 18/723,977

(22) PCT Filed: Dec. 13, 2022
(86) PCT No.: PCT/US2022/052676

§ 371 Date: Jun. 25, 2024

Related U.S. Application Data
(60) Provisional application No. 63/295,255, filed on Dec. 30, 2021.

(51) Int. Cl. H01J 37/32

(52) U.S. Cl. CPC H01J 37/32183; H01J 37/3299; H01J 2237/332; H01J 2237/334

(57) ABSTRACT

A transformer coupled capacitive tuning (TCCT) match network includes coarse and fine adjustment circuits. The coarse adjustment circuit receives a first RF signal and includes a first tune variable capacitance circuit and a first load variable capacitance circuit. The first tune variable capacitance circuit adjusts a frequency of the first RF signal to generate a second RF signal. The first load variable capacitance circuit is connected to a ground reference terminal and configured to adjust an impedance of the TCCT match network. The fine adjustment circuit includes a second tune variable capacitance circuit and a second load variable capacitance circuit. The second tune variable capacitance circuit fine tunes a frequency of the second RF signal. The second load variable capacitance circuit is connected to the ground reference terminal and fine tunes the impedance of the transformer coupled capacitive tuning match network.

### CROSS-REFERENCE TO RELATED APPLICATIONS

This application claims the benefit of U.S. Provisional Application No. 63/295,255, filed on Dec. 30, 2021. The entire disclosure of the above application is incorporated herein by reference.

### FIELD

The present disclosure relates to rapid etch and deposition alternating processes and systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

During manufacturing of semiconductor devices, etch processes and deposition processes may be performed within a processing chamber. Ionized gas, or plasma, can be introduced into the plasma chamber to etch (or remove) material from a substrate such as a semiconductor wafer, and to sputter or deposit material onto the substrate. Creating plasma for use in manufacturing or fabrication processes typically begins by introducing process gases into the processing chamber. The substrate is disposed in the processing chamber on a substrate support such as an electrostatic chuck or a pedestal.

The processing chamber may include transformer coupled plasma (TCP) reactor coils. A radio frequency (RF) signal, generated by a power source, is supplied to the TCP reactor coils. A dielectric window, constructed or a material such as ceramic, is incorporated into an upper surface of the processing chamber. The dielectric window allows the RF signal to be transmitted from the TCP reactor coils into the interior of the processing chamber. The RF signal excites gas molecules within the processing chamber to generate plasma.

The TCP reactor coils are driven by a transformer coupled capacitive tuning (TCCT) match network. The TCCT match network receives the RF signal supplied by the power source and enables tuning of power provided to the TCP reactor coils. The TCCT match network may include variable capacitors. Each of the variable capacitors includes a stationary electrode and a movable electrode. Position of the movable electrode relative to the stationary electrode is directly related to a capacitance of the corresponding capacitor. The movable electrode can be moved via a motor to different positions relative to the stationary electrode.

Power supplied to each of the TCP reactor coils is based on positions of the movable electrodes of the variable capacitors relative to the respective stationary electrodes. A ratio of power between TCP coils is also based on the positions of the movable electrodes. One or more power ratios provided during an etch process can be different from one or more power ratios provided during a deposition process.

### SUMMARY

According to certain embodiments, the present disclosure discloses a transformer coupled capacitive tuning match network. The transformer coupled capacitive tuning match network includes a coarse adjustment circuit and a fine adjustment circuit. The coarse adjustment circuit is configured to receive a first radio frequency (RF) signal and includes a first tune variable capacitance circuit and a first load variable capacitance circuit. The first tune variable capacitance circuit is configured to adjust a frequency of the first RF signal to generate a second RF signal. The first load variable capacitance circuit is connected to a ground reference terminal and configured to adjust an impedance of the transformer coupled capacitive tuning match network. The fine adjustment circuit includes a second tune variable capacitance circuit and a second load variable capacitance circuit. The second tune variable capacitance circuit is configured to fine tune a frequency of the second RF signal. A capacitance range of the second tune variable capacitance circuit is smaller than a capacitance range of the first tune variable capacitance circuit. The second load variable capacitance circuit is connected to the ground reference terminal and is configured to fine tune the impedance of the transformer coupled capacitive tuning match network. A capacitance range of the second load variable capacitance circuit is smaller than a capacitance range of the first load variable capacitance circuit.

In some embodiments, the second tune variable capacitance circuit is connected in parallel with the first tune variable capacitance circuit. The second load variable capacitance circuit is connected in parallel with the first load variable capacitance circuit.

In some embodiments, the first tune variable capacitance circuit includes a first variable capacitor. The second tune variable capacitance circuit includes a second variable capacitor connected in parallel with the first variable capacitor. The first load variable capacitance circuit includes a third variable capacitor. The second load variable capacitance circuit includes a fourth variable capacitor connected in parallel with the third variable capacitor.

In some embodiments, the first tune variable capacitance circuit includes a first variable capacitor. The second tune variable capacitance circuit includes first capacitors connected in parallel with the first variable capacitor. The first load variable capacitance circuit includes a second variable capacitor. The second load variable capacitance circuit includes second capacitors connected in parallel with the second variable capacitor.

In some embodiments, the second tune variable capacitance circuit includes a third variable capacitor connected in series with a first fixed capacitor. The second load variable capacitance circuit includes a fourth variable capacitor connected in series with a second fixed capacitor.

In some embodiments, the transformer coupled capacitive tuning match network further includes: a first motor configured to change a capacitance of the first tune variable capacitance circuit; a second motor configured to change a capacitance of the first load variable capacitance circuit; a first relay configured to change a capacitance of the second tune variable capacitance circuit; and a second relay configured to change a capacitance of the second load variable capacitance circuit.

According to some embodiments, the present disclosure discloses a system that includes the transformer coupled capacitive tuning match network and one or more controllers configured to: perform a rapid alternating process including iteratively switching between an etch process and a deposition process; and set the fine adjustment circuit to be in a first state during the etch process and in a second state during the deposition process.

In some embodiments, the one or more controllers are configured to change a state of at least one of the second tune variable capacitance circuit or the second load variable capacitance circuit while transitioning between the etch process and the deposition process.

In some embodiments, the system further includes a sensor configured to measure a phase and magnitude of the first RF signal. The one or more controllers are configured to, based on the phase and magnitude of the first RF signal, adjust at least one of a capacitance of the first tune variable capacitance circuit or a capacitance of the first load variable capacitance circuit.

In some embodiments, the second tune variable capacitance circuit includes a first relay. The first relay is configured to switch between a first capacitance and a second capacitance. The second load variable capacitance circuit includes a second relay. The second relay is configured to switch between a third capacitance and a fourth capacitance.

According to some embodiments, the present disclosure discloses a system that includes the transformer coupled capacitive tuning match network and one or more controllers configured to: perform a rapid alternating process including iteratively switching between an etch process and a deposition process; and set states of the first relay and the second relay to be in a first configuration during the etch process and in a second configuration during the deposition process.

In some embodiments, the one or more controllers are configured to: transition the first relay between the first capacitance and the second capacitance when transitioning between the etch process and the deposition process; and refrain from transitioning the second relay between the third capacitance and the fourth capacitance when transitioning between the etch process and the deposition process.

In some embodiments, the one or more controllers are configured to: transition the first relay between the first capacitance and the second capacitance when transitioning between the etch process and the deposition process; and transition the second relay between the third capacitance and the fourth capacitance when transitioning between the etch process and the deposition process.

According to some embodiments, the present disclosure discloses a rapid alternating processing method that includes: setting capacitance of a first tune variable capacitance circuit of a transformer coupled capacitive tuning match network, where the first tune variable capacitance circuit is configured to adjust a frequency of a first RF signal to generate a second RF signal; setting capacitance of a first load variable capacitance circuit, which is connected to a ground reference terminal and configured to adjust an impedance of the transformer coupled capacitive tuning match network; and setting capacitance of a second tune variable capacitance circuit and a second load variable capacitance circuit for an etch process. The second tune variable capacitance circuit is configured to fine tune a frequency of the second RF signal. A capacitance range of the second tune variable capacitance circuit is smaller than a capacitance range of the first tune variable capacitance circuit. The second variable load capacitance circuit is connected to the ground reference terminal and configured to fine tune the impedance of the transformer coupled capacitive tuning match network. A capacitance range of the second load variable capacitance circuit is smaller than a capacitance range of the first load variable capacitance circuit. The method further includes: performing the etch process; adjusting capacitance of at least one of the second tune variable capacitance circuit or the second load variable capacitance circuit for a deposition process; and performing the deposition process.

In some embodiments, the rapid alternating processing method further includes: iteratively switching between the etch process and the deposition process; and setting the second tune variable capacitance circuit to be in a first state during the etch process and in a second state during the deposition process.

In some embodiments, the rapid alternating processing method further includes: iteratively switching between the etch process and the deposition process; and setting the second load variable capacitance circuit to be in a first state during the etch process and in a second state during the deposition process.

In some embodiments, the rapid alternating processing method further includes: iteratively switching between the etch process and the deposition process; and changing a state of the second tune variable capacitance circuit and a state of the second load variable capacitance circuit while transitioning between the etch process and the deposition process.

In some embodiments, the rapid alternating processing method further includes: measuring a phase and magnitude of the first RF signal; and based on the phase and magnitude of the first RF signal, adjusting at least one of a capacitance of the first variable tune capacitance circuit or a capacitance of the first variable load capacitance circuit.

In some embodiments, the rapid alternating processing method further includes: iteratively switching between the etch process and the deposition process; and controlling states of a first relay and a second relay to be in a first state during the etch process and in a second state during the deposition process. The second tune variable capacitance circuit includes the first relay. The first relay is configured to switch between a first capacitance and a second capacitance. The second load variable capacitance circuit includes the second relay. The second relay is configured to switch between a third capacitance and a fourth capacitance.

In some embodiments, the rapid alternating processing method further includes: transitioning the first relay between the first capacitance and the second capacitance when transitioning between the etch process and the deposition process; and refraining from transitioning the second relay between the third capacitance and the fourth capacitance when transitioning between the etch process and the deposition process.

In some embodiments, the rapid alternating processing method further includes: transitioning the first relay between the first capacitance and the second capacitance when transitioning between the etch process and the deposition process; and transitioning the second relay between the third capacitance and the fourth capacitance when transitioning between the etch process and the deposition process.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system incorporating a TCP circuit and a RF power ratio switching system including speed placement capacitance circuits according to some embodiments of the present disclosure;

FIG. 2 is a functional block diagram of an example of the TCP circuit of FIG. 1 including a TCCT match network with the speed placement capacitance circuits according to some embodiments of the present disclosure;

FIG. 3 is a schematic view of the TCP circuit of FIG. 2 according to some embodiments of the present disclosure;

FIG. 4 is an example Smith chart illustrating impedance points respectively for etch and deposition processes of a rapid alternating process according to some embodiments of the present disclosure; and

FIGS. 5A-5B illustrate a substrate processing method including a rapid alternating process including high-speed impedance adjustment according to some embodiments of the present disclosure.

In the drawings, reference numbers may be reused to identify similar and/or identical elements.

### DETAILED DESCRIPTION

A traditional TCCT match network may include a load capacitor and a tune capacitor. The load capacitor is connected to a ground reference and used to compensate for changes in load impedances. The tune capacitor is used to adjust frequency of RF power supplied to TCP reactor coils. Both load and tune capacitors include a stationary electrode and a movable electrode. The TCP reactor coils may include an inner coil and an outer coil. The inner coil is disposed within the outer coil. A ratio of power suppled to the inner coil relative to power supplied to the outer coil is adjusted by moving the moveable electrodes of the capacitors. The moveable electrodes may be moved via mechanical components, such as a leadscrews, cams, cam followers, brackets, counterbalances, etc. and motors (e.g., linear and/or rotary motors). The traditional techniques for moving moveable electrodes are too slow to satisfy speed requirements for a rapid alternating process (RAP), which includes rapidly switching between etch and deposition processes. The duration of each etch process and each deposition process may be 1 second or less and a speed requirement for transitioning between two impedance states (one for etch and another for deposition) may be less than 0.1 seconds.

For a RAP, such as a Borsch process that includes deep silicon etching, two etch and deposition tune points exist for a TCCT match network. The first tune point is for etch and the second tune point is for deposition. The two tune points refer to two impedance arrangements of the match network, where each impedance arrangement has a respective tune capacitance and load capacitance. Because traditional TCCT match networks have not been quick enough to transition between the two tune points, a mid-point is often selected between the two tune points in an attempt to satisfy both etch and deposition requirements. Frequency of the generated RF signal is then adjusted via the RF generator as opposed to adjusting a capacitance of a tune capacitor of a TCCT match network. Sometimes this approach however does not satisfy, for example, frequency and reflected power requirements of the TCCT match network for both etch and deposition processes.

The examples set forth herein include TCCT match networks that can quickly transition between different impedance states for both tune circuits and load circuits of the TCCT match networks. The tune circuits adjust frequency of RF signals output from the TCCT match networks. The load circuits adjust impedances of the TCCT match network and are used to compensate for load changes between etch and deposition processes. The load changes may be due to changes in types of processing gases, processing gas pressures, and/or power settings. The quick transitioning satisfies frequency and reflected power requirements for both etch and deposition processes.

Each of the TCCT match networks includes a coarse adjustment circuit and a fine adjustment circuit. The coarse adjustment circuit includes coarse tune and load capacitance circuits for coarsely setting tune and load impedance parameters of the TCCT match network. The fine adjustment circuit includes fine tune and load capacitance circuits for finely setting tune and load impedance parameters of the TCCT match network.

In one embodiment, two tune points, one for etch and the other one for deposition of a RAP, are selected that are near each other. For example, a tune capacitance for etch may be within a first predetermined range (e.g., 5-50 pico-farads (pF)) of a tune capacitance for deposition. Similarly, a load capacitance for etch may be within a second predetermined range (e.g., 5-100 pF) of a load capacitance for deposition. Other predetermined ranges may be implemented. The predetermined ranges may be different or the same. Also, the predetermined range for tune may be smaller or larger than the predetermined range for load.

Prior to or during the RAP, coarse tune and load capacitances are preset and fixed to be the same for both the etch process and the deposition process. Capacitances of the coarse tune and load capacitance circuits are not adjusted during the RAP. Fine tune and load capacitances of the fine tune and load capacitance circuits may be preset and/or adjusted during the RAP. A capacitance range of the fine tune capacitance circuit is smaller (or a percentage) of the coarse tune capacitance circuit. Similarly, a capacitance range of the fine load capacitance circuit is smaller (or a percentage) of the coarse load capacitance circuit. In one embodiment, a difference in capacitances of the tune adjustment circuit respectively for the two tune points is greater than a difference in capacitances of the load adjustment circuit respectively for the two tune points. Both of the tune points are stable during the entire RAP.

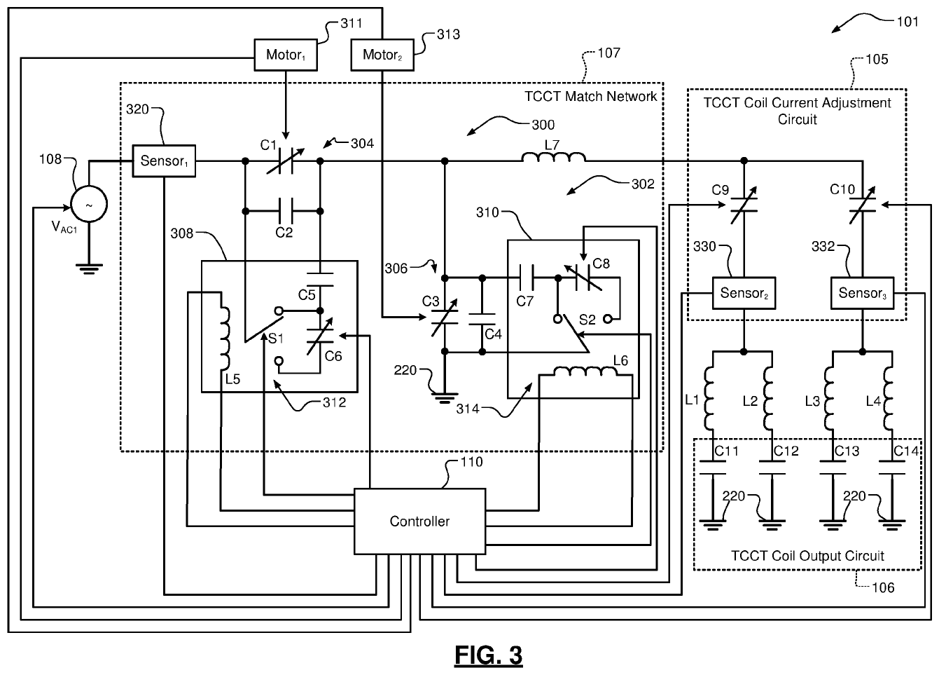

Traditional TCCT match networks take longer than 1 second to switch the impedance state between etch and deposition, but the examples disclosed herein including that shown in FIG. 3 can reduce the switch time to be less than 1 second as further described below. The examples include coarse adjustment and fine tune adjustment circuits. Each of the fine tune adjustment circuits includes tune variable capacitance and variable load capacitance circuits having capacitance ranges that are smaller than capacitance ranges of tune variable capacitance and load capacitance circuits of the corresponding one of the coarse adjustment circuits. The capacitances of the fine tune adjustment circuits are able to quickly switch between different capacitances due to the corresponding capacitance ranges of the fine tune adjustment circuits and the corresponding circuitry to controlling the transitioning between different capacitance states. Another advantage of the embodiment of FIG. 3 is the precision in tuning/switching comparing to the existing mechanical systems. The fine adjustment circuits include relays for quick and precise switching between different capacitance states.

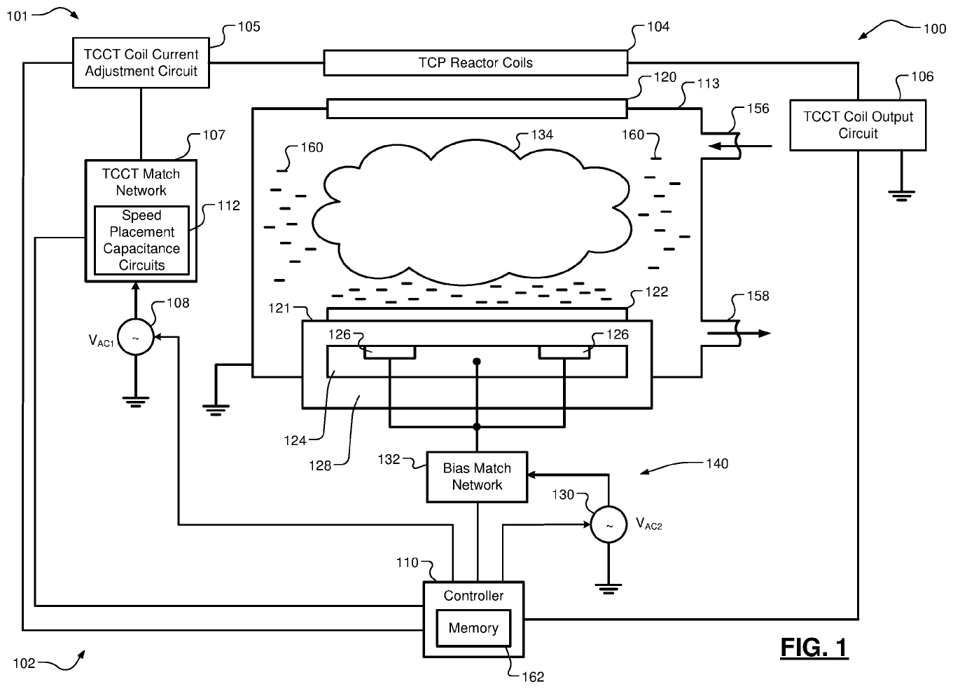

FIG. 1 shows an example substrate processing tool 100 that incorporates a TCP circuit 101 and a RF power ratio switching system 102. The TCP circuit 101 includes TCP reactor coils 104, a TCCT coil current adjustment circuit 105, a TCCT coil output circuit 106, and a TCCT match network 107. The RF power ratio switching system 102 includes the TCCT match network 107, a first RF generator 108 and a controller 110. The TCCT match network 107 includes speed placement capacitance circuits 112, which are used for quick fine tune adjustments of capacitances of tune and load capacitance circuits of the TCCT match network 107. Examples of the tune and load capacitance circuits are shown in FIG. 3.

The substrate processing tool 100 further includes a plasma processing chamber 113. The TCP reactor coils 104 are disposed outside and above the plasma processing chamber 113. The first RF generator 108 provides a first RF source signal. The TCCT (or first) match network 107 is included between the first RF generator 108 and the TCP reactor coils 104. The TCCT match network 107 enables tuning of power provided to the TCP reactor coils 104.

The plasma processing chamber 113 includes a ceramic window 120, which is located adjacent the TCP reactor coils 104 and allows efficient transmission of the first RF source signal into the plasma processing chamber 113 for plasma generation purposes. A substrate support 121 such as an electrostatic chuck, a pedestal or other suitable substrate support is disposed at the bottom of the plasma processing chamber 113. The substrate support 121 supports a substrate 122. If the substrate support 121 is an electrostatic chuck, the substrate support 121 includes electrically conductive portions 124 and 126, which are electrically isolated from each other. The substrate support 121 is surrounded by an insulator 128 and is capacitively coupled to the substrate 122. By applying a DC voltage across the conductive portions 124, 126, an electrostatic coupling is created between the conductive portions 124, 126 and the substrate 122. This electrostatic coupling attracts the substrate 122 against the substrate support 121.

The plasma processing tool 100 further includes a bias RF generator 130, which is connected to a bias (or second) match network 132. The second match network 132 is connected between the bias RF generator 130 and the substrate support 121. The second match network 132 matches an impedance (e.g., 500) of the bias RF generator 130 to an impedance of the substrate support 121 and plasma 134 in the plasma processing chamber 113 as seen by the second match network 132. The controller 110 controls operation of the RF generators 108, 130 based on a recipe and outputs of one or more sensors, such as voltage sensors, current sensors, phase sensors, etc. Example sensors are shown in FIG. 3. In some embodiments, the controller 110 is implemented as two or more controllers.

In operation, a gas capable of ionization flows into the plasma processing chamber 113 through the gas inlet 156 and exits the plasma processing chamber 113 through the gas outlet 158. The first RF signal is generated by the RF generator 108 and is delivered to the TCP reactor coil 114. The first RF signal radiates from the TCP reactor coils 104 through the window 120 and into the plasma processing chamber 113. This causes the gas within the plasma processing chamber 113 to ionize and form the plasma 134. The plasma 134 produces a sheath 160 along walls of the plasma processing chamber 113. The plasma 134 includes electrons and positively charged ions. The electrons, being much lighter than the positively charged ions, tend to migrate more readily, generating DC bias voltages and DC sheath potentials at inner surfaces of the plasma processing chamber 113. An average DC bias voltage and a DC sheath potential at the substrate 122 affects the energy with which the positively charged ions strike the substrate 122. This energy affects processing characteristics such as rates at which etching or deposition occurs.

The controller 110 may adjust the bias RF signal generated by the RF generator 130 to change the amount of DC bias and/or a DC sheath potential near/at the substrate 122. The controller 110 may compare outputs of the sensors and/or representative values derived based on the outputs to one or more set point values. The set point values may be predetermined and stored in a memory 162 of the controller 110. The bias RF signal may be adjusted based on differences between (i) the outputs of the sensors and/or the representative values and (ii) the one more set point values. The bias RF signal passes through the bias match network 132. An output provided by the bias match network 132 (referred to as a matched signal) is then passed to the substrate support 121. The bias RF signal is passed to the substrate 122 through the insulator 128.

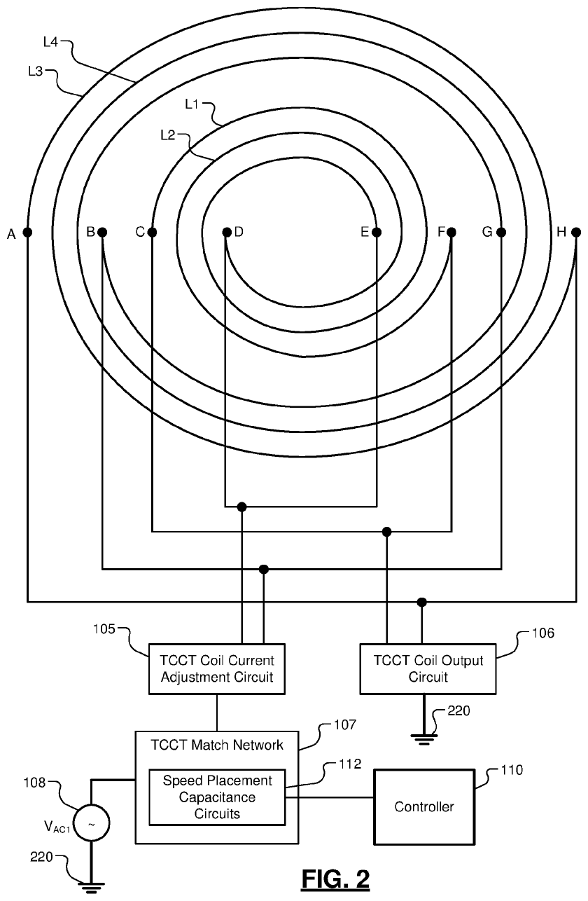

FIG. 2 shows the TCP circuit 101 that includes the TCP reactor coils 104 (shown as inner coils L1, L2 and outer coils L3, L4), the TCCT coil current adjustment circuit 105, the TCCT coil output circuit 106, and the TCCT match network 107 of FIG. 1. The inner coils L1, L2 and outer coils L3, L4 may be spiral-shaped as shown or may have a different shape and/or configuration.

The TCCT coil current adjustment circuit 105 is connected to the inner coils L1, L2 at coil ends D and E and to the outer coils L3, L4 at coil ends B and G. The TCCT coil output circuits 106 are connected to the inner coils L1, L2 at coil ends C and F and to the outer coils L3, L4 at coil ends A and H. The TCCT coil current adjustment circuit 105 receive power from the RF generator 108, which is connected to a reference terminal (or ground reference terminal) 220. The TCCT coil output circuits 106 are connected to the ground reference terminal 220.

The TCCT match network 107 includes the speed placement capacitance circuits 112, which adjust frequency and/or RF power supplied from the TCCT coil current adjustment circuit 105 to the coils L1-L4. The change in RF power changes a RF power ratio between the inner coils L1, L2 and the outer coils L3, L4. The controller 110 is connected to and adjusts capacitances of the speed placement capacitance circuits 112 to adjust the frequency, supplied RF power, and RF power ratio.

FIG. 3 shows the TCP circuit 101 that includes the TCCT match network 107, which is configured to match an impedance downstream from the TCCT match network 107 to an impedance upstream from the TCCT match network, typically the impedances are approximately 50 Ohms (Ω). This is performed to minimize the amount of reflected power back to the RF generator 108. The TCCT match network 107 includes a coarse adjustment circuit 300 and a fine adjustment circuit 302. The coarse adjustment circuit 300 includes a first tune variable capacitance circuit 304 and a first load variable capacitance circuit 306. The fine adjustment circuit 302 includes (i) a second tune variable capacitance circuit 308 connected in parallel with the first tune variable capacitance circuit 304, and (ii) a second load variable capacitance circuit 310 connected in parallel with the first load variable capacitance circuit 306. The speed placement capacitance circuits 112 of FIGS. 1-2 may be implemented as the variable capacitance circuits 308, 310.

The first tune variable capacitance circuit 304 includes a first coarse tune variable capacitor C1 and may include one or more additional capacitors (e.g., capacitor C2 is shown connected in parallel with capacitor C1). The first coarse variable capacitance circuit 306 includes a first coarse load variable capacitor C3 and may include one or more additional capacitors (e.g., capacitor C4 is shown connected in parallel with capacitor C3). In one embodiment, one or more of the capacitors C2 and C4 are not included. Capacitances of the capacitors C1, C3 are adjusted by the controller 110 via respective motors 311, 313. The capacitors C1, C3 may have stationary and movable electrodes. The movable electrodes move relative to the stationary electrodes via the motors 311, 313.

The second tune variable capacitance circuit (also referred to as a first speed placement capacitance circuit) 308 includes a first relay 312, a fixed capacitor C5 and a variable capacitor C6. A variable capacitance range of the second tune variable capacitance circuit 308 is smaller than (or a fraction of) a variable capacitance range of the first tune variable capacitance circuit 304. The fixed capacitor C5 is connected in series with the variable capacitor C6. Capacitor C5 and/or capacitor C6 are connected in parallel with the capacitors C1, C2 via the switch S1 of the first relay 312. The first relay 316 includes a first inductor (or coil) L5, which when powered switches the switch S1 between (i) a first state connecting the capacitor C5 in parallel with the capacitors C1, C2, and (ii) a second state connecting the collective series of capacitors C5 and C6 in parallel with each of the capacitors C1, C2. In one embodiment, the capacitor C5 is connected in parallel with the capacitor C1 and/or C2 when performing an etch process and both capacitors C5, C6 are connected in parallel with the capacitor C1 and/or C2 when performing a deposition process. In another embodiment, the capacitor C5 is connected in parallel with the capacitor C1 and/or C2 when performing a deposition process and both capacitors C5, C6 are connected in parallel with the capacitor C1 and/or C2 when performing an etch process.

The second load variable capacitance circuit (also referred to as a second speed placement capacitance circuit) 310 includes a second relay 314, a fixed capacitor C7 and a variable capacitor C8. A variable capacitance range of the second load variable capacitance circuit 310 is smaller than (or a fraction of) a variable capacitance range of the first load variable capacitance circuit 306. The fixed capacitor C7 is connected in series with the variable capacitor C8. Capacitor C7 and/or capacitor C8 are connected in parallel with the capacitors C3, C4 via the switch S2 of the second relay 314. The second relay 314 includes a second inductor (or coil) L6, which when powered switches the switch S2 from (i) a first state connecting the capacitor C7 in parallel with the capacitors C3, C4, and (ii) a second state connecting the collective series of capacitors C7 and C8 in parallel with each of the capacitors C3, C4. Capacitors C3, C4 and switch S2 are connected to the ground reference terminal 220. In one embodiment, the capacitor C7 is connected in parallel with the capacitor C3 and/or C4 when performing an etch process and both capacitors C7, C8 are connected in parallel with the capacitor C3 and/or C4 when performing a deposition process. In another embodiment, the capacitor C7 is connected in parallel with the capacitor C3 and/or C4 when performing a deposition process and both capacitors C7, C8 are connected in parallel with the capacitor C3 and/or C4 when performing an etch process. The switches S1, S2 of the relays 312, 314 may be switched in less than 0.2 milliseconds (ms).

The TCCT match network 107 further includes a first sensor 320, which detects phase and magnitude of the RF signal generated by the RF generator 108. The controller 110 based on the output of the first sensor 320 adjusts capacitances of the capacitors C1, C3 and may adjust the capacitances of C6, C8.

The TCCT match network 107 is connected to the TCCT coil current adjustment circuit 105 via an inductor L7. The capacitors C1, C2 are connected in series with the inductor L7 between the sensor 320 and the TCCT current adjustment circuit 105. The capacitors C3, C4 are connected in series with the inductor L7 between the ground reference terminal 220 and the TCCT current adjustment circuit 105.

The TCCT coil current adjustment circuit 105 includes a variable capacitor C9 and a second sensor 330 and another variable capacitor C10 and a third sensor 332. The second sensor is connected in series with the variable capacitor C9 between the inductor L7 (or output of the TCCT match network 107) and the inner coils L1, L2. The third sensor is connected in series with the variable capacitor C10 between the inductor L7 and the outer coils L3, L4. The sensors 330, 332 measure current through the capacitors C9, C10. The controller 110 adjusts the capacitances of C9, C10 based on the amounts of current through C9, C10 and supplied to the inner coils L1, L2 and the outer coils L3, L4.

The TCCT coil output circuit 106 includes capacitors C11-C14, which are connected respectively to the coils L1-L4 and to the ground reference terminal 220. Each of the capacitors C11-C14 are connected in series with a respective one of the coils L1-L4 and to the ground reference terminal 220.

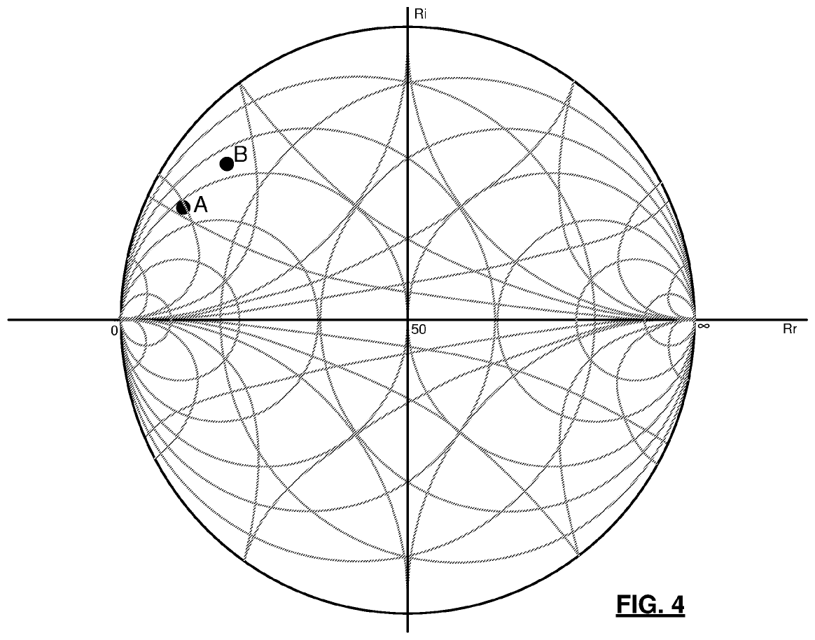

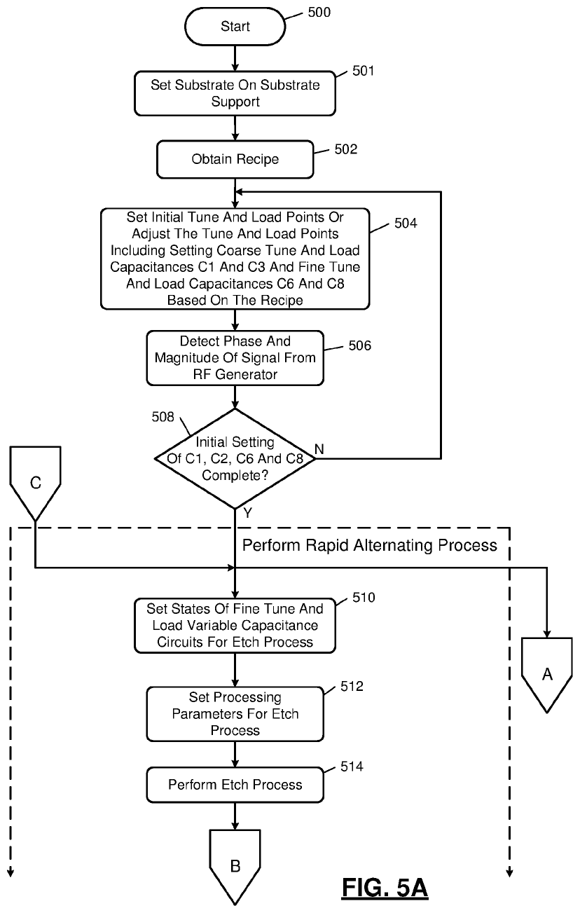

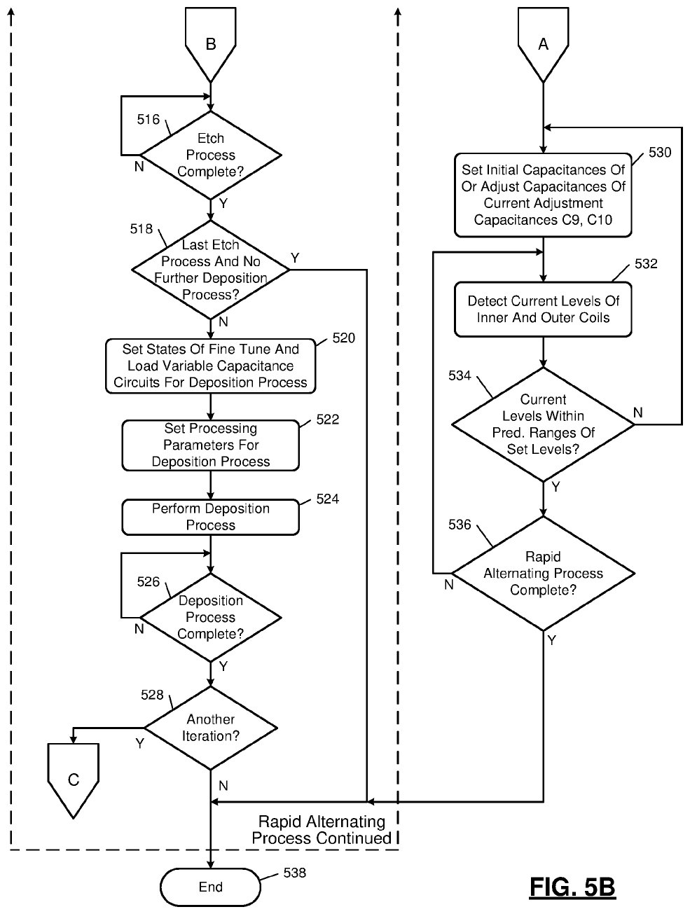

FIG. 4 shows an example Smith chart illustrating two example impedance points respectively for etch and deposition processes of a rapid alternating process. A first tune point A is shown for one of the etch and deposition processes and a second tune point B is shown for the other one of the etch and deposition processes. In the example method of FIG. 5, an RAP is performed, which includes iteratively switching between performing an etch process and a deposition process. The controller 110 of FIGS. 1-3 changes states of the speed placement capacitance circuits 112 (or 308, 310) for the etch and deposition processes. In one embodiment, the controller 110 changes the state of the second tune variable capacitance circuit 308 and does not change the state of the second load variable capacitance circuit 310 when switching between the etch and deposition states. In another embodiment, the controller 110 changes the states of both of the variable capacitance circuits 308, 310 when switching between the etch and deposition states. The Smith chart includes real and imaginary axes for resistance, where the center of the Smith chart is the 50Ω point. Points A and B are shown as examples. Locations of points A and B on the Smith chart may be different than shown. Also, the distance between points A and B may be different from that shown.

FIGS. 5A-5B show an example substrate processing method including a rapid alternating process including high-speed impedance adjustment. The following operations may be iteratively performed and are primarily described with respect to the implementations of FIGS. 1-4. The method may begin at 500. At 501, a substrate may be set on the substrate support 121. At 502, the controller 110 obtains a recipe.

At 504, the controller 110 sets initial tune and load points or adjusts the tune and load points based on the recipe. This may include setting coarse tune and load capacitances of the capacitors C1 and C3. The controller 110 may also set the capacitances of the capacitors C6, C8 of the variable capacitance circuits 308, 310. For example, the types of processing gases, gas pressures, and RF power parameters of the recipe have associated loads. The capacitances of the capacitors C3, C8 may be set to compensate for the loads associated with the gases, gas pressures and RF power parameters in the recipe for minimum reflected power.

At 506, the controller 110 may detect via the sensors 320 the phase and magnitude of a RF power signal output from the RF generator 108. At 508, the controller 110 may determine whether the settings of C1, C3, C6, C8 are appropriate for the measured phase and magnitude of the RF power signal. This may include looking up values for C1, C3, C6, C8, for example, in a look-up table (LUT) stored in the memory 162. If the settings of C1, C3, C6 and C8 match the looked-up values, then a RAP process may be performed, otherwise capacitances of one or more of the capacitors C1, C3, C6, C8 may be adjusted at 504.

The RAP process includes iteratively switching between performing an etch process and performing a deposition process. The RAP process may include hundreds of etch and deposition processes, where each etch process removes a thin layer of material within a feature (e.g., a hole or a trench). Each etch process may remove a predetermined number of micrometers (μm) of material. By performing numerous etch and deposition processes to form a feature, the amount of “bowing” of feature sidewalls is minimized. Each deposition process provides a chemically inert passivation layer that minimizes etching of sidewalls during the subsequent etch processes. The etch processes may be nearly isotropic plasma etch processes, which include primarily etching at a bottom of a feature and not along sides of the feature. The RAP process may begin at 510.

At 510, the controller 110 sets states of fine tune and load variable capacitance circuits 308, 310 for the etch process based on the portion of the recipe associated with the etch process. The states may be set based on types of processing gases, gas pressures, RF power levels of the RF generator 108 during the etch process, etc. As an example, sulfur hexafluoride (SF6) may be supplied to the processing chamber 113 during the etch process. In one embodiment, the controller 110 also sets and/or changes the states of the variable capacitance circuits 308, 310 based on changes in capacitances of the capacitors C9, C10, which may be changed during, for example, operation 530. This may be performed to minimize RF reflected power.

At 512, the controller 110 sets processing parameters for the etch process. This may include supplying gases, such as SF6, setting chamber pressures, gas flow rates, temperatures, etc. for the etch process. At 514, the controller 110 performs the etch process. At 516, the controller 110 determines whether the etch process is complete. If yes, operation 518 may be performed.

At 518, the controller 110 determines whether the current etch process is a last etch process and no further deposition process is to be performed. If no, operation 520 is performed, otherwise the method may end at 538.

At 520, the controller 110 sets states of fine tune and load variable capacitance circuits 308, 310 for the deposition process based on the portion of the recipe associated with the deposition process. The states may be set based on processing gases, chamber pressures, gas pressures, RF power levels of the RF generator 108 during the deposition process, etc. As an example, octafluorocyclobutane (C4F8) may be supplied to the processing chamber 113 during the deposition process. The states of the fine tune and load variable capacitances 308, 310 may be changed by changing states of the switches S1, S2. In one embodiment, the controller 110 also sets and/or changes the states of the variable capacitance circuits 308, 310 based on changes in capacitances of the capacitors C9, C10, which may be changed during, for example, operation 530. This may be performed to minimize RF reflected power.

The controller 110 may determine whether to change the state of switch S2 based on a detected and/or determined amount of change in the load. For example if the gases, gas pressures, and/or RF power levels are changed such that a change in the state of the fine load variable capacitance circuit 310 is appropriate, then the state of switch S2 is changed for the deposition process. If the change in load is minimal between the etch and the deposition processes, then the controller 110 may refrain from changing the state of the switch S2.

At 522, the controller 110 sets processing parameters for the deposition process. This may include supplying gases, such as C4F8, setting chamber pressures, gas flow rates, temperatures, etc. for the deposition process. At 524, the controller 110 performs the deposition process. At 526, the controller 110 determines whether the deposition process is complete. If yes, operation 528 may be performed.

At 528, the controller 110 may determine whether to perform another iteration of the RAP. If yes, operation 510 may be performed, otherwise the method may end at 538.

The following operations 530 532, 534, 536 may be performed prior to and/or during the RAP. The operations 530 532, 534, 536 may be performed in parallel with the operations of the RAP. At 530, the controller 110 may set initial capacitances of the current adjustment capacitances C9, C10 or adjust capacitances of the current adjustment capacitances C9, C10 for the etch or deposition process being performed. In one embodiment, the capacitances of the capacitors C9, C10 are adjusted such that current flow through one of the capacitors C9, C10 is increased while current flow through the other one of the capacitors C9, C10 is decreased. This is done to minimize the amount of reflected power.

At 532, the controller 110 detects current levels of the inner coils L1, L2 and the outer coils L3, L4 via the sensors 330, 332. By detecting the current levels through the capacitors C9, C10, the controller 110 is able to estimate the current levels of the inner coils L1, L2 and the outer coils L3, L4 based on known inductances of the coils L1-L4 and capacitances of the capacitors C11-C14.

At 534, the controller 110 determines whether the current levels of the coils L1-L4 are within predetermined ranges of target levels. If yes, operation 536 may be performed, otherwise operation 530 may be performed. At 536, the controller 110 determines whether the RAP is completed. If yes, the method may end at 538, otherwise operation 532 may be performed.

The above-described operations are meant to be illustrative examples. The operations may be performed sequentially, synchronously, simultaneously, continuously, during overlapping time periods or in a different order depending upon the application. Also, any of the operations may not be performed or skipped depending on the implementation and/or sequence of events.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A transformer coupled capacitive tuning match network comprising:
a coarse adjustment circuit configured to receive a first radio frequency (RF) signal and comprising
a first tune variable capacitance circuit configured to adjust a frequency of the first RF signal to generate a second RF signal, and
a first load variable capacitance circuit connected to a ground reference terminal and configured to adjust an impedance of the transformer coupled capacitive tuning match network; and
a fine adjustment circuit comprising
a second tune variable capacitance circuit configured to fine tune a frequency of the second RF signal, wherein a capacitance range of the second tune variable capacitance circuit is smaller than a capacitance range of the first tune variable capacitance circuit, and
a second load variable capacitance circuit connected to the ground reference terminal and configured to fine tune the impedance of the transformer coupled capacitive tuning match network, wherein a capacitance range of the second load variable capacitance circuit is smaller than a capacitance range of the first load variable capacitance circuit.

2. The transformer coupled capacitive tuning match network of claim 1, wherein:
the second tune variable capacitance circuit is connected in parallel with the first tune variable capacitance circuit; and
the second load variable capacitance circuit is connected in parallel with the first load variable capacitance circuit.

3. The transformer coupled capacitive tuning match network of claim 1, wherein:
the first tune variable capacitance circuit comprises a first variable capacitor;
the second tune variable capacitance circuit comprises a second variable capacitor connected in parallel with the first variable capacitor;
the first load variable capacitance circuit comprises a third variable capacitor; and
the second load variable capacitance circuit comprises a fourth variable capacitor connected in parallel with the third variable capacitor.

4. The transformer coupled capacitive tuning match network of claim 1, wherein:
the first tune variable capacitance circuit comprises a first variable capacitor;
the second tune variable capacitance circuit comprises a first plurality of capacitors connected in parallel with the first variable capacitor;
the first load variable capacitance circuit comprises a second variable capacitor; and
the second load variable capacitance circuit comprises a second plurality of capacitors connected in parallel with the second variable capacitor.

5. The transformer coupled capacitive tuning match network of claim 4, wherein:
the second tune variable capacitance circuit comprises a third variable capacitor connected in series with a first fixed capacitor; and
the second load variable capacitance circuit comprises a fourth variable capacitor connected in series with a second fixed capacitor.

6. The transformer coupled capacitive tuning match network of claim 1, further comprising:
a first motor configured to change a capacitance of the first tune variable capacitance circuit;
a second motor configured to change a capacitance of the first load variable capacitance circuit;
a first relay configured to change a capacitance of the second tune variable capacitance circuit; and
a second relay configured to change a capacitance of the second load variable capacitance circuit.

7. A system for substrate processing, comprising:
the transformer coupled capacitive tuning match network of claim 1; and
one or more controllers configured to
perform a rapid alternating process including iteratively switching between an etch process and a deposition process, and
setting the fine adjustment circuit to be in a first state during the etch process and in a second state during the deposition process.

8. The system of claim 7, wherein the one or more controllers are configured to change a state of at least one of the second tune variable capacitance circuit or the second load variable capacitance circuit while transitioning between the etch process and the deposition process.

9. The system of claim 7, further comprising a sensor configured to measure a phase and magnitude of the first RF signal,
wherein the one or more controllers are configured to, based on the phase and magnitude of the first RF signal, adjust at least one of a capacitance of the first tune variable capacitance circuit or a capacitance of the first load variable capacitance circuit.

10. The transformer coupled capacitive tuning match network of claim 1, wherein:
the second tune variable capacitance circuit comprises a first relay;
the first relay is configured to switch between a first capacitance and a second capacitance;
the second load variable capacitance circuit comprises a second relay; and
the second relay is configured to switch between a third capacitance and a fourth capacitance.

11. A system for substrate processing, comprising:
the transformer coupled capacitive tuning match network of claim 10; and
one or more controllers configured to
perform a rapid alternating process including iteratively switching between an etch process and a deposition process, and
set states of the first relay and the second relay to be in a first configuration during the etch process and in a second configuration during the deposition process.

12. The system of claim 11, wherein the one or more controllers are configured to:
transition the first relay between the first capacitance and the second capacitance when transitioning between the etch process and the deposition process; and
refrain from transitioning the second relay between the third capacitance and the fourth capacitance when transitioning between the etch process and the deposition process.

13. The system of claim 11, wherein the one or more controllers are configured to:
transition the first relay between the first capacitance and the second capacitance when transitioning between the etch process and the deposition process; and
transition the second relay between the third capacitance and the fourth capacitance when transitioning between the etch process and the deposition process.

14. A rapid alternating processing method comprising:
setting capacitance of a first tune variable capacitance circuit of a transformer coupled capacitive tuning match network, wherein the first tune variable capacitance circuit is configured to adjust a frequency of a first radio frequency (RF) signal to generate a second RF signal;
setting capacitance of a first load variable capacitance circuit, which is connected to a ground reference terminal and configured to adjust an impedance of the transformer coupled capacitive tuning match network;
setting capacitance of a second tune variable capacitance circuit and a second load variable capacitance circuit for an etch process, wherein
the second tune variable capacitance circuit is configured to fine tune a frequency of the second RF signal,
a capacitance range of the second tune variable capacitance circuit is smaller than a capacitance range of the first tune variable capacitance circuit,
the second load variable capacitance circuit is connected to the ground reference terminal and configured to fine tune the impedance of the transformer coupled capacitive tuning match network, and
a capacitance range of the second load variable capacitance circuit is smaller than a capacitance range of the first load variable capacitance circuit;
performing the etch process;
adjusting capacitance of at least one of the second tune variable capacitance circuit or the second load variable capacitance circuit for a deposition process; and
performing the deposition process.

15. The rapid alternating processing method of claim 14, further comprising:
iteratively switching between the etch process and the deposition process; and
setting the second tune variable capacitance circuit to be in a first state during the etch process and in a second state during the deposition process.

16. The rapid alternating processing method of claim 14, further comprising:
iteratively switching between the etch process and the deposition process; and
setting the second load variable capacitance circuit to be in a first state during the etch process and in a second state during the deposition process.

17. The rapid alternating processing method of claim 14, further comprising:
iteratively switching between the etch process and the deposition process; and
changing a state of the second tune variable capacitance circuit and a state of the second load variable capacitance circuit while transitioning between the etch process and the deposition process.

18. The rapid alternating processing method of claim 14, further comprising:
measuring a phase and magnitude of the first RF signal; and
based on the phase and magnitude of the first RF signal, adjusting at least one of a capacitance of the first tune variable capacitance circuit or a capacitance of the first load variable capacitance circuit.

19. The rapid alternating processing method of claim 14, further comprising:
iteratively switching between the etch process and the deposition process; and
controlling states of a first relay and a second relay to be in a first state during the etch process and in a second state during the deposition process,
wherein
the second tune variable capacitance circuit comprises the first relay,
the first relay is configured to switch between a first capacitance and a second capacitance,
the second load variable capacitance circuit comprises the second relay, and
the second relay is configured to switch between a third capacitance and a fourth capacitance.

20. The rapid alternating processing method of claim 19, further comprising:
transitioning the first relay between the first capacitance and the second capacitance when transitioning between the etch process and the deposition process; and
refraining from transitioning the second relay between the third capacitance and the fourth capacitance when transitioning between the etch process and the deposition process.

21. The rapid alternating processing method of claim 19, further comprising:
transitioning the first relay between the first capacitance and the second capacitance when transitioning between the etch process and the deposition process; and
transitioning the second relay between the third capacitance and the fourth capacitance
